(19) United States
(12) Patent Application Publication
(10) Pub. No.: US 2007/0164447 A1
(43) Pub. Date: Jul. 19, 2007

(54) Semiconductor package and fabricating method thereof

(76) Inventors: Kwun-Yao Ho, Hsin-Tien City (TW); Moriss Kung, Hsin-Tien City (TW)

Correspondence Address: J.C. Patents, Inc., Suite 250, 4 Venture, Irvine, CA, 92618, US

(21) Appl. No.: 11/445,868

(22) Filed: Jun. 2, 2006

(30) Foreign Application Priority Data
Jan. 17, 2006 (TW) 95101687

(51) Int. Cl. H01L 23/48

(52) U.S. Cl. 257/778

(57) ABSTRACT

A semiconductor package including a die, a substrate and bumps is provided. The die has die pads arranged on an active surface thereof and a first passivation layer. The first passivation layer is disposed on the active surface and has first openings for exposing the die pads, respectively. The substrate has a substrate surface, substrate pads and a second passivation layer. The substrate pads are arranged on the substrate surface. The second passivation layer is arranged on the substrate surface and has a second opening for exposing the substrate pads and a portion of the substrate surface. The bumps are arranged on the die pads, respectively. Each bump is connected to one of the substrate pads through a compression bonding process, and the die is electrically connected to the substrate through the bumps. A distance between the first passivation layer and the substrate pads is smaller than 50 μm.

### CROSS-REFERENCE TO RELATED APPLICATION

This application claims the priority benefit of Taiwan application serial no. 95101687, filed on Jan. 17, 2006. All disclosure of the Taiwan application is incorporated herein by reference.

### BACKGROUND OF THE INVENTION

1. Field of the Invention

The present invention generally relates to a semiconductor device, and more particularly, to a semiconductor package.

2. Description of Related Art

In the semiconductor industry, the manufacturing of integrated circuits (ICs) can be divided into three stages: IC design, IC fabrication process and IC package. In the IC fabrication process, the die is formed after a series of wafer preparation, IC fabrication and wafer dicing processes. The die has an active surface where the active device of the wafer is. After the IC fabrication process is completed, a plurality of die pads are formed on the active surface of the wafer, which is covered with a passivation layer. Partial surface of each die pad is exposed to the outside, such that the die formed by wafer dicing can be electrically connected to a carrier through the die pads. The carrier can be a lead frame of a package substrate. And the die can be connected to the carrier by way of wire bonding or flip chip bonding, such that the die pads of the die can be electrically connected to the terminal pads of the carrier to form a semiconductor package.

In terms of the flip chip bonding technology, after the die pads of the wafer are formed, a bumping process is performed to form a bump on each die pad to be electrically connected to a package substrate. Since the bumps are arranged on the active surface of the die in an array manner, the flip chip bonding technology is suitable for the semiconductor package of high contact count and high density, such as the flip chip/ball grid array type package which is broadly used in the semiconductor package industry. Additionally, compared with the wire bonding technology, the bumps can provide a shorter transmission path between the die and the carrier, such that the flip chip bonding technology can enhance the electrical performance of the semiconductor package.

FIG. 1 is a schematic cross-sectional view showing a conventional flip chip package. Referring to FIG. 1, a conventional flip chip package 100 comprises a die 100, a package substrate 120, a plurality of solder bumps 130, an under bump metallurgic (UBM) layer 140 and an under fill layer 150. The die 110 has an active surface 112 and a plurality of die pads 114 disposed on the active surface 112. Besides, the die 110 further comprises a passivation layer 116 over the active surface 112 for protecting the die 110 and exposing each die pad 114.

The package substrate 120 has a substrate surface 122, a plurality of substrate pads 124 and a solder mask 126. These substrate pads 124 are arranged on the substrate surface 122, and the solder mask 126 is arranged on the substrate surface 122 and exposes the substrate pads 124. Each die pad 114 is electrically connected to the corresponding substrate pad 124 through one of the solder bumps 130. A material of the solder bumps 130 can be lead containing solder or lead-free solder.

The UBM layers 140 are disposed between the die pads 114 and the solder bumps 130. The UBM layer 140 may comprise an adhesion layer, a barrier layer and a wetting layer sequentially formed on the die pad 114. The UBM layer 140 is adapted for enhancing the adhesion between the solder bumps 130 and the die pads 114 and preventing electro-migration.

The under fill layer 150 is disposed between the die 110 and the package substrate 120 and encloses the solder bumps 130. The under fill layer 150 is used to protect the solder bumps 130 and provide a buffer effect against the thermal strain mismatch between the package substrate 120 and die 110 when heated.

However, when the die and the package substrate of the conventional flip chip package undergo the flip chip bonding process, a high temperature reflow process must be performed to melt each solder bump, to form a bump having a spherical shape for electrically connecting one of the die pads and the corresponding substrate pad. Accordingly, the fabrication process of the conventional flip chip package is more complex and expensive. In addition, the flip chip package must undergo the above-mentioned high temperature reflow process, therefore it is necessary to use the solder mask disposed on the package substrate to prevent the unnecessary electrical connection between the solder bumps when melted. As a result, the miniaturization of the conventional flip chip package is limited.

### SUMMARY OF THE INVENTION

As embodied and broadly described herein, the present invention provides a semiconductor package comprising a die, a substrate and a plurality of bumps. The die has an active surface, a plurality of die pads and a first passivation layer. These die pads are arranged on the active surface, and the first passivation layer is disposed on the active surface and has a plurality of first openings for exposing the die pads, respectively. Besides, the substrate has a substrate surface, a plurality of substrate pads and a second passivation layer. The substrate pads are arranged on the substrate surface, and the second passivation layer is arranged on the substrate surface and has a second opening for exposing the substrate pads and a portion of the substrate surface. Furthermore, the bumps are arranged on the die pads, respectively. Each bump is connected to one of the substrate pads through a compression bonding process, and the die is electrically connected to the substrate through the bumps.

As embodied and broadly described herein, the present invention provides a fabricating method of forming a semiconductor package. The fabricating method comprises providing a die, providing a substrate, disposing a bump on one of the die pad, and compressing the die onto the second opening of the substrate to joint the bump and one of the substrate pads. The die having an active surface, a plurality of die pads and a first passivation layer. Besides, the die pads are arranged on the active surface, and the first passivation layer is disposed on the active surface and has a plurality of first openings for exposing the die pads, respectively. The substrate having a substrate surface, a plurality of substrate pads and a second passivation layer, wherein the substrate pads are arranged on the substrate surface, the second passivation layer is arranged on the substrate surface and has a second opening for exposing the substrate pads and a portion of the substrate surface.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view showing a conventional flip chip package.

FIGS. 2 and 3 are schematic, cross-sectional diagrams illustrating a fabrication process of a semiconductor package according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

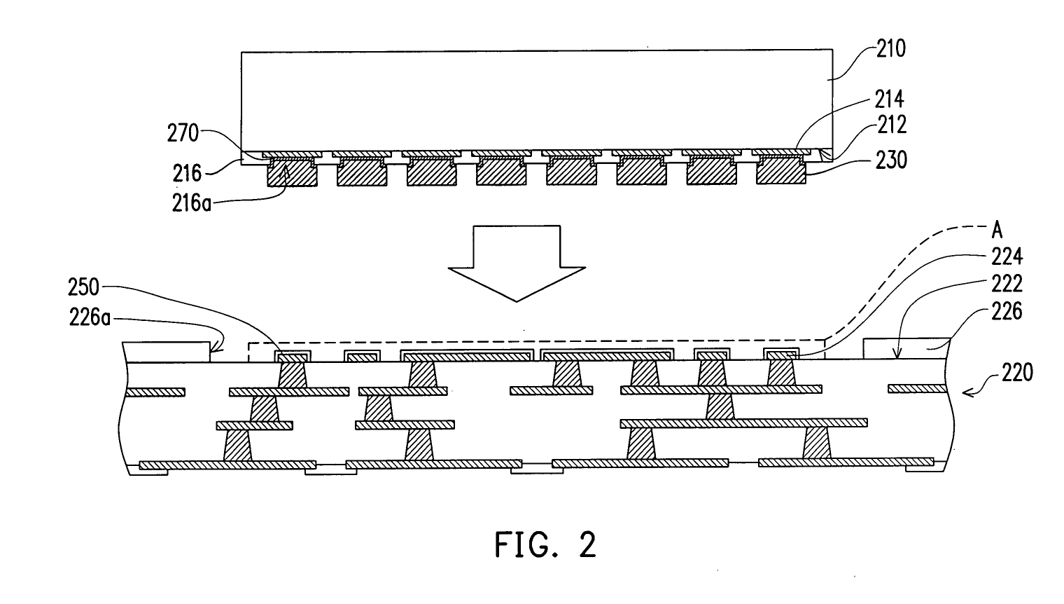

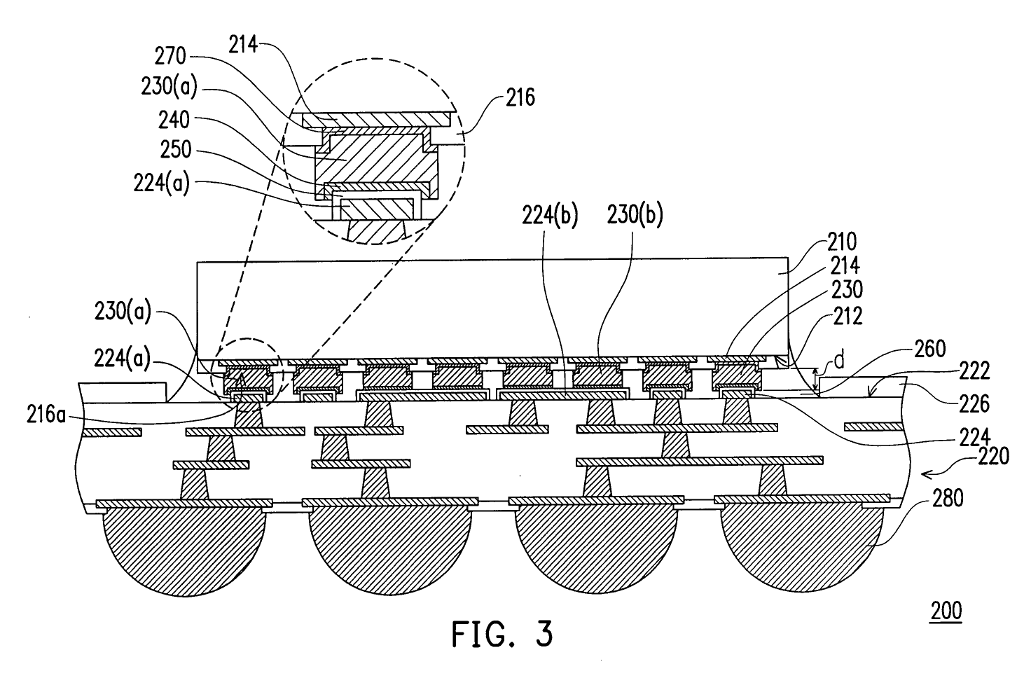

FIGS. 2 and 3 are schematic, cross-sectional diagrams illustrating a fabrication process of a semiconductor package according to an embodiment of the present invention. Referring to FIGS. 2 and 3, the semiconductor package 200 of this embodiment, such as a flip chip package, has a die 210, a substrate 220 and a plurality of bumps 230. The die 210 has an active surface 212, a plurality of die pads 214 and a first passivation layer 216. These die pads 214 can be arranged on the active surface 212 in a array manner, and the first passivation layer 216 is disposed on the active surface 212. The first passivation layer has a plurality of first openings 216a for exposing the die pads 214, respectively. Besides, the first passivation layer 216 can be a stress buffer layer (SBL) made of benzocyclobutene (BCB) for protecting the die 210.

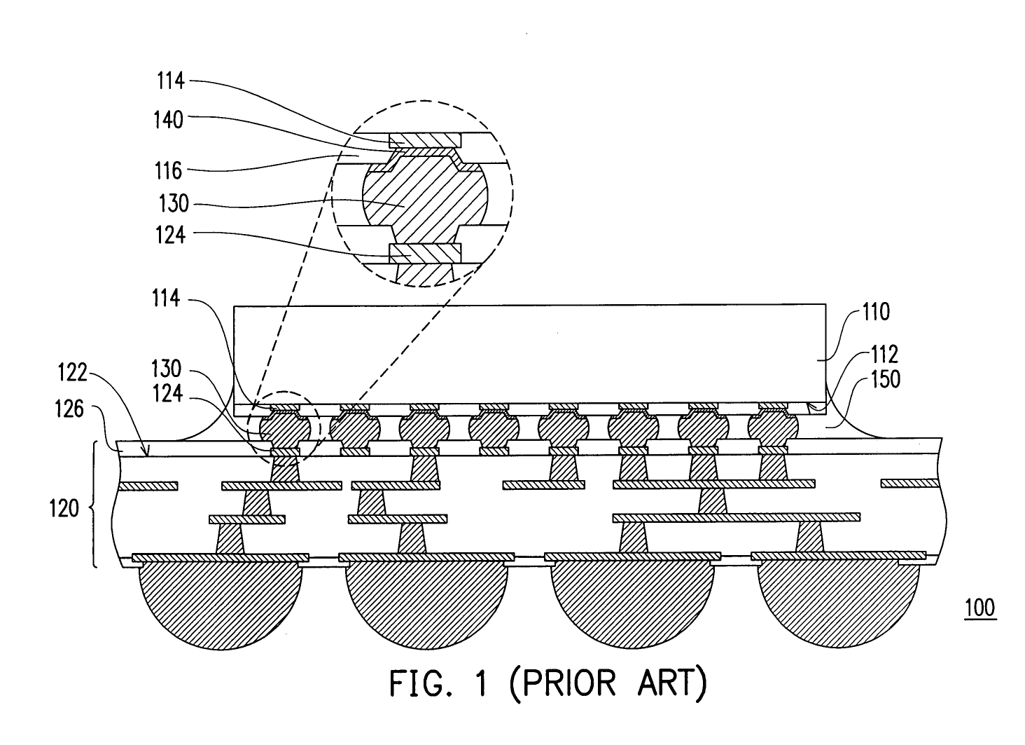

The substrate 220, which may be a plastic package substrate, a ceramic package substrate, or a silicon substrate used in semiconductor fabricating industry, has a substrate surface 222, a plurality of substrate pads 224 and a second passivation layer 226. The substrate pads 224 are arranged on the substrate surface 222, and the second passivation layer 226 is arranged on the substrate surface 222 and has a second opening 226a for exposing the substrate pads 224 and a portion of the substrate surface 222, to protect the circuit on the substrate surface 222 of the substrate 220. Additionally, a material of the second passivation layer 226 can be similar to that of the solder mask 126 (shown in FIG. 1) of the conventional flip chip package 100.

From FIGS. 2 and 3, the bumps 230 are arranged on the die pads 214, respectively. Each bump 230 is connected to one of the substrate pads 224 through a compression bonding process, and the die 210 is electrically connected to the substrate 220 through the bumps 230. A distance d between the first passivation layer 216 and the substrate pads 244 is smaller than 50 μm.

The bumps 230 may be of a ball shape, a spheroid shape or a pillar shape, and a material of the bumps 230 may comprise lead-free material such as gold, copper, tin, nickel and the alloy thereof. It should be noted that the compression bonding process would be performed during a heating process to heat the die and the bumps at the temperature higher than room temperature. Besides, the compression bonding process would be performed after a pre-heating process to heat the die and the bumps at the temperature higher than room temperature. In other words, the process of compressing each bump 230 onto one of the substrate pads 224 can be a pure compression bonding process or a thermal compression bonding process. Additionally, in this embodiment, if the thermal compression bonding process is performed, a melting point of the bumps 230 is at least 50° C. higher than the temperature during the compressional bonding process, which joints the bumps 230 and the substrate pads 224, to prevent the bumps 230 from melting during the thermal compression bonding process.

It should be noted that in the above-mentioned compression bonding process, the bumps 230 do not need to undergo the high temperature reflow process as the solder bumps 130 (as shown in FIG. 1) of the conventional flip chip package 100 (That is, the bumps 230 are not melted), therefore the fabrication process of the semiconductor package 200 is simplified and the cost is lower. Besides, these bumps 230 would not completely melt to a liquid state during compression, which avoids unnecessary electrical connection among the bumps, and accordingly the second passivation layer 226 is not required within a compression region A where the die 210 is compressed onto the substrate 220. That is, the compression region A is completely exposed by the second opening 226a of the second passivation layer 226, and further the thickness of the semiconductor package 200 of this embodiment is reduced and the density of the substrate pads 224 is increased.

Please refer to FIG. 3. After the compression bonding process, one of the substrate pads 224 (such as the substrate pad 224(a) shown in FIG. 3) would be partially embedded in one of the bumps 230 (such as the bump 230(a) shown in FIG. 3), to enhance the bonding strength between the substrate pad 224(a) and the bump 230(a). Besides, one of the substrate pads 224 (such as the substrate pad 224(b ) shown in FIG. 3) is connected to two of the bumps 230 (such as the bump 230(b) shown in FIG. 3), and the substrate pad 224(b) can be conducted to a ground or a power source.

Referring to FIGS. 2 and 3, the semiconductor package 200 of this embodiment further comprises an intermetallic compound 240 disposed between the bumps 230 and the substrate pads 224, and a melting point of the intermetallic compound 240 is smaller than that of the bumps 230. The semiconductor package 200 of this embodiment further comprises a surface finish layer 250 disposed on the substrate pads 224, and the thickness of the surface finish layer 250 is smaller than 5 μm. If the material of the substrate pads 224 is copper, the surface finish layer 250 can protect the exposed surface of the substrate pads 224 from oxidation. It should be noted that when each bump 230 is compressed onto one of the substrate pads 224, a reaction would occur between the bumps 230 and the surface of the substrate pads 224 or the surface finish layer 250, to form the intermetallic compound 240.

Please continue to refer to FIG. 3. The semiconductor package 200 of this embodiment further comprises an under fill layer 260, an UBM layer 270 and a plurality of electrical contacts 280. The under fill layer 260 is disposed between the die 210 and the substrate 220, and covers the bumps 230. The under fill layer 260 is adapted for protecting the bumps 230 and providing a buffer effect against the thermal strain mismatch between the substrate 220 and die 210 when heated. The UBM layer 270 is disposed between the bumps 230 and the die pads 214, and the UBM layer 270 may comprise an adhesion layer and a barrier layer sequentially formed on the die pad 214. The UBM layer 270 is adapted for enhancing the adhesion between each bump 230 and the corresponding die pad 214 and preventing electro-migration.

Additionally, these electrical contacts 280 are arranged on a surface of the substrate 220 opposite to the substrate surface 222 for electrically connecting with the next level of electronic devices (not shown herein). In this embodiment, the electrical contacts 280 are conductive balls serving as an input/output interface for ball grid array (BGA). The electrical contacts 280 may also be conductive pins or conductive columns serving as an input/output interface for pin grid array (PGA) or column grid array (CGA), respectively, which are not shown in the drawing.

In summary, the semiconductor package of the present invention has at least the following advantages:

(1) In the fabrication process of compressing the bumps onto the corresponding substrate pads, the bumps do not undergo the high temperature reflow process (that is, the bumps are not melted), and accordingly the fabrication process of the semiconductor package of the present invention is simplified and the cost is lower.

(2) These bumps would not completely melt during compression, which avoids unnecessary electrical connection among the bumps, and accordingly the second passivation layer is not required within a compression region where the die is compressed onto the substrate. That is, the compression region is completely exposed by the second opening of the second passivation layer, and further the thickness of the semiconductor package of the present invention is decreased.

(3) The thickness of the package structure of the present invention is decreased, and accordingly the bumps can provide a shorter transmission path between the die and the substrate compared with the prior art, thereby enhancing the electrical performance of the semiconductor package.

(4) These bumps would not completely melt during compression, which avoids unnecessary electrical connection among the bumps, and therefore the distance between the bumps can be shorter, thus enhancing the layout density of the die and the substrate.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor package, comprising:
a die having an active surface, a plurality of die pads and a first passivation layer, wherein the die pads are arranged on the active surface, and the first passivation layer is disposed on the active surface and has a plurality of first openings for exposing the die pads, respectively;
a substrate having a substrate surface, a plurality of substrate pads and a second passivation layer, wherein the substrate pads are arranged on the substrate surface, the second passivation layer is arranged on the substrate surface and has a second opening for exposing the substrate pads and a portion of the substrate surface; and
a plurality of bumps arranged on the die pads, respectively, each bump being connected to one of the substrate pads through a compression bonding process, and the die being electrically connected to the substrate through the bumps, wherein a distance between the first passivation layer and the substrate pads is smaller than 50 μm.

2. The semiconductor package according to claim 1, wherein a melting point of the bumps is at least 50° C. higher than an operation temperature of the compression bonding process.

3. The semiconductor package according to claim 1, wherein one of the substrate pads is partially embedded in one of the bumps.

4. The semiconductor package according to claim 1, wherein a material of the bumps comprises a lead-free material.

5. The semiconductor package according to claim 1, wherein a material of the bumps comprises gold, copper, tin or nickel and an alloy thereof.

6. The semiconductor package according to claim 1, further comprising an intermetallic compound disposed between the bumps and the substrate pads, wherein a melting point of the intermetallic compound is smaller than that of the bumps.

7. The semiconductor package according to claim 1, further comprising a surface finish layer disposed between the bumps and the substrate pads, wherein a thickness of the surface finish layer is smaller than 5 μm.

8. The semiconductor package according to claim 1, further comprising an under fill layer disposed between the die and the substrate, and covering the bumps.

9. The semiconductor package according to claim 1, further comprising an under bump metallurgic layer disposed between the bumps and the die pads.

10. The semiconductor package according to claim 1, wherein the substrate is a plastic package substrate, a ceramic substrate, or a silicon substrate.

11. The semiconductor package according to claim 1, wherein one of the substrate pads is connected to at least two of the bumps.

12. A fabricating method of forming a semiconductor package, comprising:
providing a die having an active surface, a plurality of die pads and a first passivation layer, wherein the die pads are arranged on the active surface, and the first passivation layer is disposed on the active surface and has a plurality of first openings for exposing the die pads, respectively;
providing a substrate having a substrate surface, a plurality of substrate pads and a second passivation layer, wherein the substrate pads are arranged on the substrate surface, the second passivation layer is arranged on the substrate surface and has a second opening for exposing the substrate pads and a portion of the substrate surface;
disposing a bump on one of the die pad; and
compressing the die onto the second opening of the substrate under an operation temperature, such that the bump jointing one of the substrate pads, wherein a melting point of the bumps 230 is at least 50° C. higher than the operation temperature.

13. The fabricating method of forming a semiconductor package according to claim 12, further comprising:
heating the bump to achieve a temperature higher than a room temperature.

14. The fabricating method of forming a semiconductor package according to claim 13, wherein the step of compressing the die onto the second opening of the substrate is performed during the step of heating the bump to achieve a temperature higher than a room temperature.

15. The fabricating method of forming a semiconductor package according to claim 13, wherein the step of compressing the die onto the second opening of the substrate is performed after the step of heating the bump to achieve a temperature higher than a room temperature.

16. The fabricating method of forming a semiconductor package according to claim 12, wherein one of the substrate pads is partially embedded in one of the bumps after the step of compressing the die onto the second opening of the substrate.

17. The fabricating method of forming a semiconductor package according to claim 12, wherein a material of the bumps comprises gold, copper, tin or nickel and an alloy thereof.

18. The fabricating method of forming a semiconductor package according to claim 12 further comprising:
disposing a surface finish layer disposed on the substrate pads.

19. The fabricating method of forming a semiconductor package according to claim 12 further comprising:
disposing an under fill layer between the die and the substrate to cover the bump.

20. The fabricating method of forming a semiconductor package according to claim 12, wherein the substrate is a plastic package substrate, a ceramic substrate or a silicon substrate.
